(19) United States
(12) Patent Application Publication
(10) Pub. No.: US 2013/0214411 A1
(43) Pub. Date: Aug. 22, 2013

(54) METAL INTERCONNECT OF SEMICONDUCTOR DEVICE AND METHOD OF MANUFACTURING THE SAME

(71) Applicant: Korea Institute of Science and Technology, (US)

(72) Inventors: Young Hwan KIM, Seoul (KR); Yong Tae KIM, Gyeonggi-do (KR); Seong Il KIM, Seoul (KR); Chun Keun KIM, Seoul (KR)

(73) Assignee: KOREA INSTITUTE OF SCIENCE AND TECHNOLOGY, Seoul (KR)

(21) Appl. No.: 13/659,345

(22) Filed: Oct. 24, 2012

(30) Foreign Application Priority Data
Feb. 16, 2012 (KR) 10-2012-0015689

(51) Int. Cl. H01L 23/48; H01L 21/768

(52) U.S. Cl. 257/741; 438/637; 257/E21.586; 257/E23.011

(57) ABSTRACT

Provided is a method of manufacturing a metal interconnect of a semiconductor device including: forming a interconnect hole by patterning an interlayer insulating film formed on a substrate; performing a nitriding treatment on a surface of the interlayer insulating film by injecting a gas including nitrogen into a deposition apparatus in which the substrate is disposed; forming a diffusion preventing film by injecting the gas including nitrogen and a metal source gas into the deposition apparatus together; filling the interconnect hole with a metal; and removing the metal formed on a part other than the interconnect hole by a chemical mechanical polishing (CMP) process. Accordingly, the mechanical strength of the interlayer insulating film is increased, thereby preventing scratches or defects that are generated during the chemical mechanical polishing process.

### CROSS-REFERENCE TO RELATED APPLICATION

This application claims priority to Korean Patent Application No. 10-2012-0015689, filed on Feb. 16, 2012, and all the benefits accruing therefrom under 35 U.S.C. §119, the contents of which in its entirety are herein incorporated by reference.

### BACKGROUND

1. Field

The following disclosure relates to a metal interconnect of a semiconductor device and a method of manufacturing the same, and in particular, to a metal interconnect of a semiconductor device having improved reliability and a method of manufacturing the same.

2. Description of the Related Art

For an increase in the degree of integration and performance improvement of a semiconductor integrated circuit, minute line widths have been demanded when devices are manufactured. In addition, metal interconnects in circuits need 6 to 7 or more layers in the case of logic circuits, and such a multi-layer line structure has been popularized.

In order to form minute lines, the wavelength of a light source used in an existing lithography apparatus has been gradually reduced. As the wavelength of the light source is reduced, resolution for clearly printing lines is increased. However, depth of focus which is a distance to which focus is brought vertically should he reduced. When such depth of focus is reduced, unevenness of formed layers is increased, and this acts as a fatal factor when lines of succeeding layers are formed. Accordingly, a planarization process is necessary for manufacturing the multi-layer line structure of a semiconductor integrated circuit.

Existing planarization techniques include reflow, spin-on-glass, etch back, and the like. However, the biggest problem of such techniques is that a degree of planarity corresponding to a required depth of focus may not be ensured as lithography techniques are developed.

In order to solve the problem, a chemical mechanical polishing (hereinafter, referred to as CMP) process technique which combines mechanical polishing and chemical polishing into a single process technique has been developed. The CMP process is a process which simultaneously uses chemical etching and mechanical polishing and is a process of supplying a polishing liquid (slurry) in which polishing particles and a chemical solution are mixed onto a polishing pad and causing a material being polished to be pressed against and come into contact with the polishing pad so as to be polished.

In addition, as RC delay time is increased due to a reduction in line widths caused by an increase in the degree of integration of integrated circuit, the material of the line has been replaced with copper from aluminum. However, it is difficult to perform etching on copper. Therefore, in order to use copper for metal interconnects, the CMP process in addition to a damascene process is necessary process for manufacturing semiconductor circuits.

In the planarization process which is performed using the CMP technique, scratches and various defects are easily generated on the polished surface due to mechanical force generated during the polishing process. In a case where such scratches and defects are generated during a metal interconnect process which is the final operation of the device manufacturing process, even though all previous device manufacturing processes are perfect, the scratches and defects cause failures due to short circuits of devices and finally have a serious effect on production yields.

In the copper line process, tetraethoxysilicate (TEOS) is mainly used as an interlayer insulating film. However, when consumables of the CMP apparatus are at the last operation, scratches are increased due to the deterioration of the consumables. Recently, as ultra-minute devices have been introduced, the management standards of scratches and defects are strict, and the replacement cycle of the consumables of the CMP apparatus has been gradually reduced.

Particularly, scratch spots generated during the copper CMP process may not have problems during a normal operation of chips at room temperature. However, the scratch spots are vulnerable to reliability evaluation at high temperature and may cause leakage current and short circuits of lines, resulting in malfunction such as an operation stop of semiconductor devices.

Therefore, a method of manufacturing metal interconnects for reducing the density of scratches and defects generated during the copper CMP process is required. Referring to Korean Patent Registration No. 0840475, in a metal interconnect formation process using a dual damascene method, a method for removing scratches generated after the copper CMP process is proposed. However, there is a problem in that additional photolithography/etching processes are needed for removing scratches.

### SUMMARY

An embodiment of the present disclosure is directed to providing a method of manufacturing a metal interconnect of a semiconductor device capable of ensuring reliability by preventing the formation of scratches and defects.

Another embodiment of the present disclosure is directed to providing a metal interconnect of a semiconductor device manufactured by the method.

In one general aspect, a method of manufacturing a metal interconnect of a semiconductor device includes: forming a interconnect hole by patterning an interlayer insulating film formed on a substrate; performing a nitriding treatment on a surface of the interlayer insulating film by injecting a gas including nitrogen into a deposition apparatus in which the substrate is disposed; forming a diffusion preventing film by injecting the gas including nitrogen and a metal source gas into the deposition apparatus together; filling the interconnect hole with a metal; and removing the metal formed on a part other than the interconnect hole by a chemical mechanical polishing (CMP) process.

In the performing of the nitriding treatment on the surface of the interlayer insulating film by injecting the gas including nitrogen, at least one gas of nitrogen (N₂), ammonia (NH₃), nitrogen monoxide (NO), and nitrogen dioxide (NO₂) may be injected.

The performing of the nitriding treatment on the surface of the interlayer insulating film by injecting the gas including nitrogen may further include applying pulse plasma power to an upper electrode and a lower electrode of the deposition apparatus.

A momentary peak voltage difference of the pulse plasma power may be maintained in a range of 1 kV to 10 kV.

The performing of the nitriding treatment on the surface of the interlayer insulating film by injecting the gas including nitrogen may further include performing a heat treatment on the surface of the substrate.

The surface of the substrate may be subjected to the heat treatment at a temperature range of 100° C. to 500° C.

The filling of the interconnect hole with the metal may further include: depositing a metal seed layer on the diffusion preventing film; and forming copper on the metal seed layer using an electroplating method.

The method of manufacturing a metal interconnect of a semiconductor device may further include forming a protective film on the metal interconnect after the CMP process.

The operations may be repeated two or more times so as to form a multi-layer metal interconnect.

In another general aspect, a metal interconnect of a semiconductor device includes: an interlayer insulating film in which a interconnect hole is formed; a hardness controlled unit which is obtained by performing a nitriding treatment on a surface of the interlayer insulating film on an upper portion of the interlayer insulating film and in the vicinity of the interconnect hole; a diffusion preventing film which is formed on the hardness controlled unit formed in the vicinity of the interconnect hole; and a metal filled in the interconnect hole.

The metal may include copper (Cu).

The interlayer insulating film may include silicon dioxide (SiO₂).

The interlayer insulating film may be made of one of tetraethoxysilicate (TEOS), high-density plasma oxide (HDP-Oxide), and borophosphosilicate glass (BPSG).

The hardness controlled unit may include silicon nitride (SiNₓ) or silicon oxynitride (SiO_{y}N_{z}).

A nitrogen concentration of the hardness controlled unit may be between about 1% to about 75%.

A dielectric constant of the hardness controlled unit may be lower than that of the interlayer insulating film by about 5% to about 15%.

The diffusion preventing film may include one of tungsten nitride (WN), tantalum nitride (TaN), and titanium nitride (TiN).

The metal interconnect of the semiconductor device may have a multi-layer structure.

The metal interconnect of the semiconductor device may further include a protective film formed on the metal.

The protective film may include silicon nitride (SiNₓ).

According to the metal interconnect of the semiconductor device and the method of manufacturing the same as described above, the mechanical strength of the surface of the interlayer insulating film is increased by performing the nitriding treatment on the surface of the interlayer insulating film, and thus scratches or defects that are generated during the chemical mechanical polishing process involved in the formation of the metal interconnect may be prevented. Therefore, a reduction in yield due to the scratches or defects of the surface of the metal interconnect is improved, and the number of scratches in units of micrometers is reduced, thereby ensuring the reliability of the semiconductor device.

In addition, the period of use of consumables of a chemical mechanical polishing apparatus is increased, and thus production costs and material costs of the semiconductor device may be reduced. Further, since additional processes and separate facilities for removing scratches or defects that are generated on the surface of the metal interconnect are not required, the manufacturing time and production costs may be reduced.

### BRIEF DESCRIPTION OF THE DRAWINGS

The above and other objects, features and advantages of the present disclosure will become apparent from the following description of certain exemplary embodiments given in conjunction with the accompanying drawings, in which:

FIG. 1 is a cross-sectional view of a metal interconnect of a semiconductor device according to an exemplary embodiment of the disclosure;

FIGS. 2A to 2F are cross-sectional views for explaining a method of manufacturing the metal interconnect of FIG. 1;

FIG. 3 is a schematic view of a deposition apparatus used for manufacturing the metal interconnect of FIG. 1;

FIG. 4 is a graph of scratch indexes of an interlayer insulating film according to the disclosure and an interlayer insulating film according to the related art; and

FIG. 5 is a graph of surface hardness changes with temperature and time of a nitriding treatment of the interlayer insulating film according to the disclosure.

[Detailed Description of Main Elements]

| | |
|---|---|
| 10: metal interconnect | 100: substrate |
| 110: interlayer insulating film | 130: hardness controlled unit |
| 150: diffusion preventing film | 170: metal |
| 190: protective film | 410: interconnect hole |
| 20: deposition apparatus | |

### DETAILED DESCRIPTION

Hereinafter, exemplary embodiments of a metal interconnect of a semiconductor device and a method of manufacturing the same according to the disclosure will be described in detail with reference to the drawings.

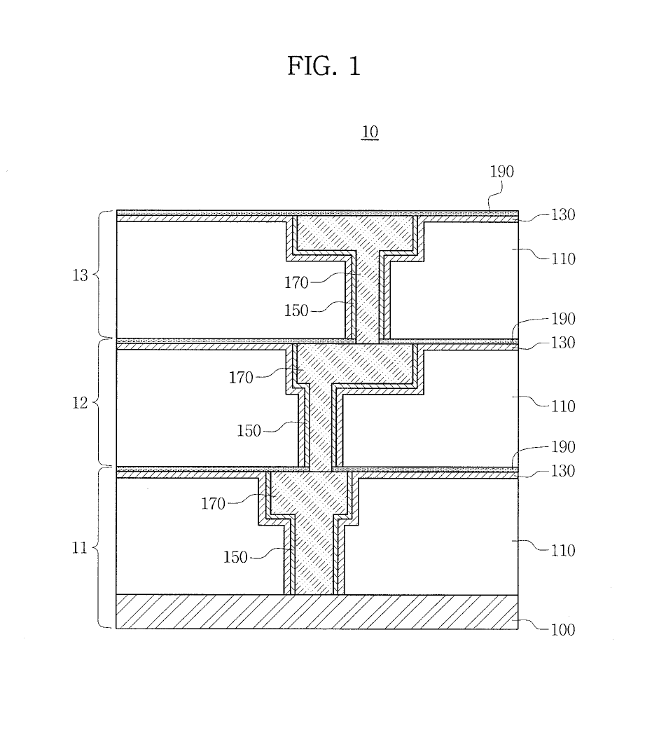

FIG. 1 is a cross-sectional view of a metal interconnect of a semiconductor device according to an exemplary embodiment of the disclosure.

Referring to FIG. 1, the metal interconnect 10 of the semiconductor device according to the exemplary embodiment of the disclosure includes: an interlayer insulating film 110 in which a interconnect hole is formed; a hardness controlled unit 130 which is formed on the upper portion of the interlayer insulating film 110 and in the vicinity of the interconnect hole; a diffusion preventing film 150 which is formed on the hardness controlled unit 130 formed in the vicinity of the interconnect hole; and a metal 170 filled in the interconnect hole.

The metal interconnect 10 may have a single-layer or multi-layer structure. In FIG. 1, a metal interconnect having a three-layer structure (11, 12, and 13) is illustrated, and the metal interconnect may be manufactured in various structures as necessary. Hereinafter, for the convenience, the first layer 11 is representatively described.

The interlayer insulating film 110 may be formed on a substrate 100, and the substrate 100 may be a silicon substrate. In addition, the interlayer insulating film 110 has the same configuration as the substrate 100, and the interconnect hole may be formed on the substrate 100. The interconnect hole is a via hole which is thereafter filled with the metal 170 to form a metal pattern.

The interlayer insulating film 110 may include silicon dioxide (SiO₂). For example, the interlayer insulating film 110 may be made of one of tetraethoxysilicate (TEOS), high-density plasma oxide (HDP-Oxide), and borophosphosilicate glass (BPSG).

The hardness controlled unit 130 is a layer formed by performing a nitriding treatment on the interlayer insulating film 110, and increases the mechanical strength, that is, hardness of the surface of the interlayer insulating film 110. Therefore, surface scratches which are generated during a chemical mechanical polishing (hereinafter, referred to as CMP) process which is a planarization process of the metal interconnect 10 may be reduced. For example, the hardness controlled unit 130 may have a hardness of higher than or equal to about 1.5 times that of the interlayer insulating film 110.

In addition, the hardness controlled unit 130 enhances the uniformity of the diffusion preventing film 150 and the metal 170 formed on the hardness controlled unit 130.

The hardness controlled unit 130 may include silicon nitride (SiNₓ) or silicon oxynitride (SiO_{y}Nₓ). The nitrogen concentration of the hardness controlled unit 130 may be higher than or equal to about 1% and less than about 100%, and for example, may be between about 1% to about 75%.

In addition, the dielectric constant of the hardness controlled unit 130 may be lower than that of the interlayer insulating film 110 by about 5% to about 15%. When the dielectric constant is reduced, the interlayer electrostatic capacity is reduced, resulting in an increase in the transmission rate of the metal interconnect 10.

The hardness controlled unit 130 is formed in the vicinity of the interconnect hole of the interlayer insulating film 110 and on the upper portion of the interlayer insulating film 110. The hardness controlled unit 130 formed on the upper portion of the interlayer insulating film 110 may be entirely or partially removed during a subsequent CMP process. In FIG. 1, it is illustrated that a part of the hardness controlled unit 130 remains.

The diffusion preventing film 150 is formed on the hardness controlled unit 130 formed in the vicinity of the interconnect hole. The diffusion preventing film 150 may also be formed on the hardness controlled unit 130 formed on the upper portion of the interlayer insulating film 110 and may be removed during the subsequent CMP process.

The diffusion preventing film 150 has a role of preventing the metal 170 from diffusing into the interlayer insulating film 110 and the substrate 100 when the metal 170 is deposited. The diffusion preventing film 150 may include one of tungsten nitride (WN), tantalum nitride (TaN), and titanium nitride (TiN).

The metal 170 fills the interconnect hole, forms the metal pattern of the metal interconnect 10, and may form a multi-layer. For example, the metal 170 may be copper (Cu). After the metal 170 is formed, a CMP process of removing metals other than the metal 170 that fills the interconnect hole is performed.

The metal interconnect 10 may further include a protective film 190 formed on the metal 170 after the CMP process is performed. The protective film 190 may include silicon nitride (SiNₓ).

In the metal interconnect 10 according to the disclosure, the hardness controlled unit 130 obtained by performing the nitriding treatment on the interlayer insulating film 110 is formed between the interlayer insulating film 110 and the diffusion preventing film 150. That is, the hardness controlled unit 130 is formed through a pre-treatment performed before depositing the diffusion preventing film 150, thereby increasing the hardness of the interlayer insulating film 110.

Therefore, a problem of a low hardness of the interlayer insulating film 110, which is a main cause of surface scratches and defects of the metal interconnect 10, is solved, and surface scratches and defects of the interlayer insulating film 110 that are generated during the subsequent CMP process may be reduced.

In addition, a cause of malfunction such as leakage current or short circuits of the metal interconnect 10 is removed, thereby ensuring the reliability of the metal interconnect 10 and the semiconductor device in which the metal interconnect 10 is used. The metal interconnect 10 is a connection line used in the semiconductor device, and the metal interconnect 10 may be applied to various semiconductor devices such as memory devices or storage devices.

Hereinafter, a method of manufacturing the metal interconnect 10 according to the exemplary embodiment of the disclosure will be described.

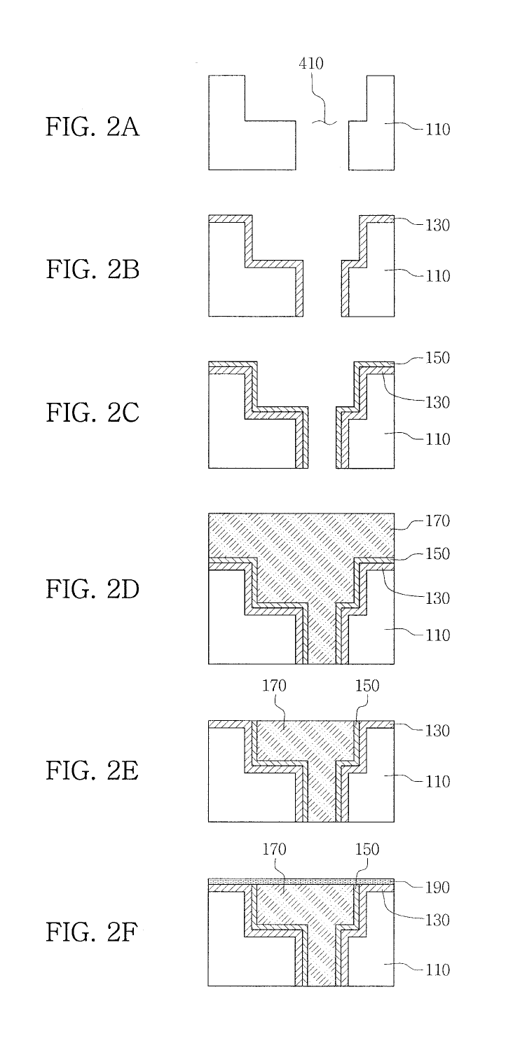

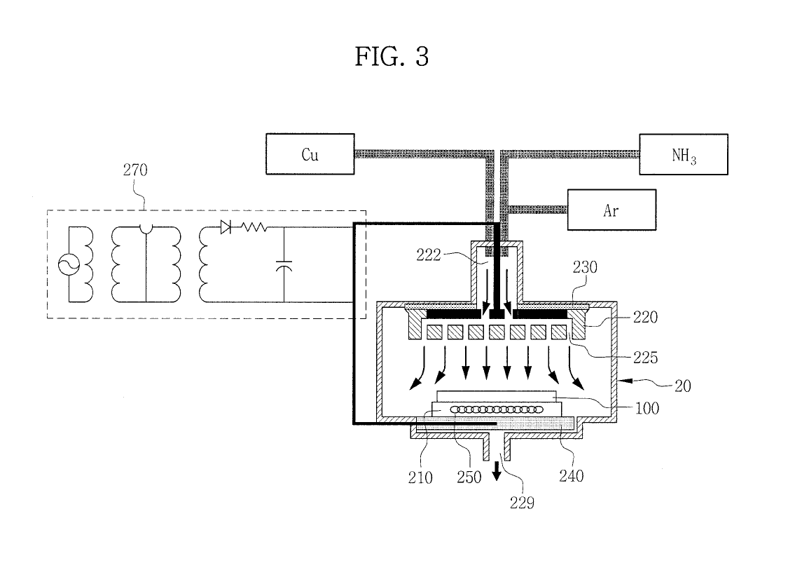

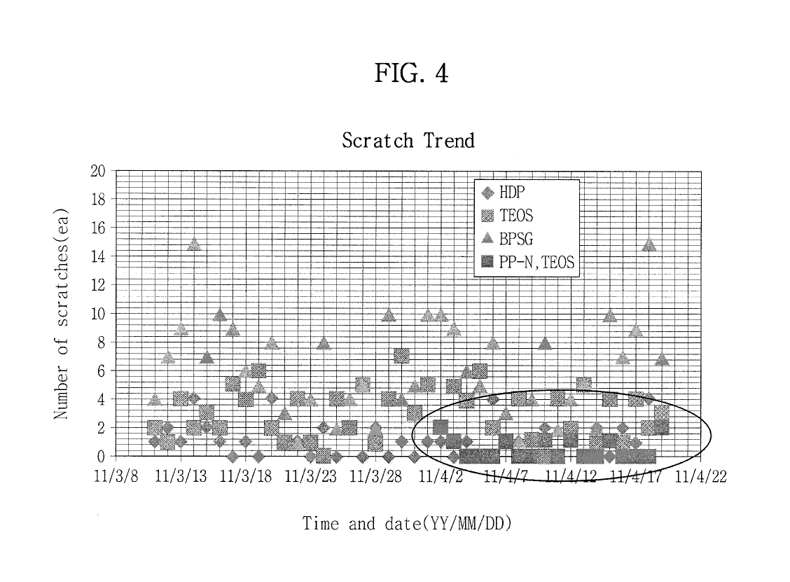

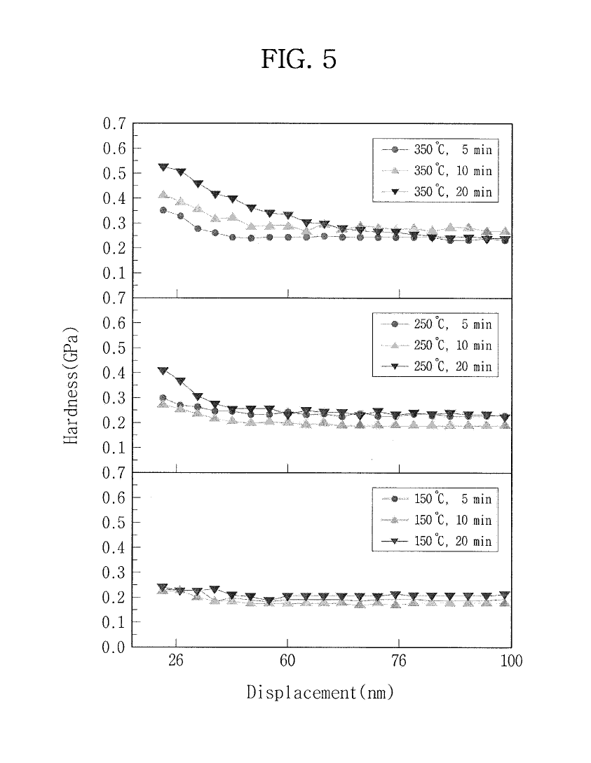

FIGS. 2A to 2F are cross-sectional views for explaining the method of manufacturing the metal interconnect of FIG. 1. FIG. 3 is a schematic view of a deposition apparatus used for manufacturing the metal interconnect of FIG. 1. FIG. 4 is a graph of scratch indexes of the interlayer insulating film according to the disclosure and an interlayer insulating film according to the related art. FIG. 5 is a graph of surface hardness changes with temperature and time of a nitriding treatment of the interlayer insulating film according to the disclosure.

Referring to FIG. 2A, a interconnect hole 410 for forming the metal pattern is formed in the interlayer insulating film 110.

The interlayer insulating film 110 may be formed by being deposited on a substrate (not shown, see FIG. 1), and the substrate may be a silicon substrate. The interlayer insulating film 110 may be deposited by an atmospheric pressure chemical vapor deposition (APCVD), low-pressure chemical vapor deposition (LPCVD), or plasma-enhanced chemical vapor deposition (PECVD) method.

The interlayer insulating film 110 may include silicon dioxide (SiO₂). For example, the interlayer insulating film 110 may be made of one of tetraethoxysilicate (TEOS), high-density plasma oxide (HDP-Oxide), and borophosphosilicate glass (BPSG).

Thereafter, the interconnect hole 410 is formed in the interlayer insulating film 110 through a photolithography and etching process. The interconnect hole 410 is a part that is thereafter filled with a metal to form a metal pattern.

In this embodiment, the interlayer insulating film 110 and the substrate 100 have separate configurations. However, the interlayer insulating film 110 and the substrate 100 may have the same configuration and the interconnect hole may be formed in the substrate 100.

Referring to FIG. 2B, the hardness controlled unit 130 is formed by performing the nitriding treatment on the surface of the interlayer insulating film 110 in which the interconnect hole 410 is formed. The hardness controlled unit 130 is formed along the interconnect hole 410 formed in the interlayer insulating film 110 and is also formed on the upper portion of the interlayer insulating film 110.

In order to form the hardness controlled unit 130, the substrate 100 (see FIG. 3) on which the interlayer insulating film 110 is formed is disposed in the deposition apparatus 20 (see FIG. 3), and a gas including nitrogen is injected into the deposition apparatus 20. The gas including nitrogen may include at least one gas of nitrogen (N₂), ammonia (NH₃), nitrogen monoxide (NO), and nitrogen dioxide (NO₂).

By injecting the gas including nitrogen to react with the interlayer insulating film 110, the exposed surface of the interlayer insulating film 110 is subjected to the nitriding treatment. That is, the surface of the interlayer insulating film 110 in the vicinity of the interconnect hole 410 and the surface of the upper portion of the interlayer insulating film 110 are subjected to the nitriding treatment, thereby generating the hardness controlled unit 130. In this case, by controlling the time of the nitriding treatment, the thickness of the hardness controlled unit 130 may be controlled.

The hardness controlled unit 130 is a layer formed by performing the nitriding treatment on the interlayer insulating film 110, and increases the mechanical strength, that is, hardness of the surface of the interlayer insulating film 110. Therefore, surface scratches which are generated during the chemical mechanical polishing (hereinafter, referred to as CMP) process which is a planarization process of the metal interconnect 10 may be reduced. For example, the hardness controlled unit 130 may have a hardness of higher than or equal to about 1.5 times that of the interlayer insulating film 110.

In addition, the hardness controlled unit 130 enhances the uniformity of the diffusion preventing film 150 and the metal 170 formed on the hardness controlled unit 130.

The hardness controlled unit 130 may include silicon nitride (SiNₓ) or silicon oxynitride (SiO_{y}N_{z}). The nitrogen concentration of the hardness controlled unit 130 may be higher than or equal to about 1% and less than about 100%, and for example, may be between about 1% to about 75%.

In addition, the dielectric constant of the hardness controlled unit 130 may be lower than that of the interlayer insulating film 110 by about 5% to about 15%. When the dielectric constant is reduced, the interlayer electrostatic capacity is reduced, resulting in an increase in the transmission rate of the metal interconnect 10.

Referring to FIG. 3, as an example of the deposition apparatus 20 used for manufacturing the metal interconnect, the deposition apparatus 20 includes a stage 210 on which the substrate 100 is disposed, a gas introduction port 222 through which a process gas is injected, a shower plate 220 having ejection holes 225 through which the process gas is ejected, and a gas discharge port 229 for discharging the process gas to the outside. In addition, the deposition apparatus 20 may further include a pulse plasma power supply 270, an upper electrode 230, a lower electrode 240, and a heater 250, as necessary.

The hardness controlled unit 130 is formed by injecting the gas including nitrogen through the gas introduction port 222 of FIG. 3. In a process of forming the metal interconnect according to the related art, a gas including nitrogen and a metal source gas (or metal precursor) are injected together into the interlayer insulating film in which the interconnect hole is formed so as to form the diffusion preventing film. However, in the disclosure, the gas including nitrogen is injected first to cause the interlayer insulating film 110 to react with nitrogen.

Therefore, separate equipment or additional raw materials are not needed, and by nitriding the interlayer insulating film 110 in vivo and in situ, the process time may be reduced.

According to an embodiment of the disclosure, in the operation of performing the nitriding treatment on the surface of the interlayer insulating film 110, pulse plasma power may be applied to the deposition apparatus 20 to accelerate the reaction of nitrogen.

The pulse plasma power generated by the pulse plasma power supply 270 is applied to the upper electrode 230 and the lower electrode 240. A momentary peak voltage difference of the pulse plasma power may be maintained in a range of about 1 kV to about 10 kV. When the pulse plasma power is applied, nitrogen becomes a radical ion state and is adsorbed onto the surface of the interlayer insulating film 110, thereby increasing the reactivity of nitrogen.

Referring to FIG. 4, experimental results of scratch generation frequencies after the CMP process is performed on the generated metal interconnect 10 according to the related art and the disclosure are shown. Scratch indexes are determined by scanning the metal interconnect 10 using discovery inspection equipment of Hitachi, Ltd. in Japan and performing a scratch inspection using a scanning electron microscope.

Specifically, a case where the interlayer insulating film is formed of high-density plasma oxide (HDP-Oxide), tetraethoxysilicate (TEOS), and borophosphosilicate glass (BPSG) according to the related art, and a case where the interlayer insulating film 100 formed of tetraethoxysilicate (TEOS) is subjected to the nitriding treatment with the pulse plasma power application so as to form the hardness controlled unit 130 (PP-N TEOS) according to the present disclosure are compared with each other.

As shown in the graph of FIG. 4, the average number of scratches formed on the interlayer insulating film according to the related art is 1.18 in high-density plasma oxide (HDP-Oxide), 3.09 in tetraethoxysilicate (TEOS), and 6.27 in borophosphosilicate glass (BPSG).

On the other hand, in the case where the interlayer insulating film 100 formed of tetraethoxysilicate (TEOS) is subjected to the nitriding treatment with the pulse plasma power application so as to form the hardness controlled unit 130 (PP-N TEOS) according to the present disclosure, the average number of scratches is 0.5, that is, is significantly reduced.

Therefore, a reduction in yield due to scratches or defects of the surface of the metal interconnect 10 is improved, and thus the reliability of the semiconductor device that includes the metal interconnect 10 may be enhanced.

In addition, in another exemplary embodiment of the disclosure, in the operation of performing the nitriding treatment on the surface of the interlayer insulating film 110, the substrate 100 may be subjected to a heat treatment simultaneously with the application of the pulse plasma power to the deposition apparatus 20 so as to increase the permeability of nitrogen. The heat treatment may be performed on the substrate 100 by the heater 250 of FIG. 3, and the surface of the substrate 100 may be subjected to the heat treatment at a temperature range of about 100° C. to about 500° C.

Referring to FIG. 5, it is seen that the hardness of the interlayer insulating film 110 is improved through the heat treatment at about 150° C. or higher. Therefore, since the hardness of the interlayer insulating film 110 is increased, scratches or defects generated in the interlayer insulating film 110 by the polishing particles in the polishing liquid (slurry) during the subsequent CMP process may be prevented.

In this embodiment, the heat treatment of the surface of the interlayer insulating film 110 is performed in the deposition apparatus 20. However, the heat treatment may also be performed outside the deposition apparatus 20. In addition, in this embodiment, in the operation of performing the nitriding treatment on the surface of the interlayer insulating film 110, the heat treatment of the substrate 100 is performed simultaneously with the application of the pulse plasma power to the substrate 100. However, the heat treatment may also be separately performed.

In addition, the thickness and properties of the hardness controlled unit 130 may be controlled by controlling a time for which the pulse plasma power is applied to the deposition apparatus 20 and a voltage of the pulse plasma power, or the heat treatment time and temperature of the substrate 100, as necessary.

Referring to FIG. 2C, the gas including nitrogen and the metal source gas (or metal precursor) are injected together into the interlayer insulating film 110 on which the hardness controlled unit 130 is formed, thereby forming the diffusion preventing film 150. The gas including nitrogen is injected while the hardness controlled unit 130 is formed and thereafter may be continuously injected to form the diffusion preventing film 150.

Since the diffusion preventing film 150 is formed on the hardness controlled unit 130, the diffusion preventing film 150 is formed on the hardness controlled unit 130 formed both in the vicinity of the interconnect hole 410 and on the upper portion of the interlayer insulating film 110. However, the diffusion preventing film 150 formed on the hardness controlled unit 130 formed on the upper portion of the interlayer insulating film 110 is removed during the subsequent CMP process.

The diffusion preventing film 150 has a role of preventing the metal 170 from diffusing into the interlayer insulating film 110 and the substrate 100 when the metal 170 is thereafter deposited. The diffusion preventing film 150 may include one of tungsten nitride (WN), tantalum nitride (TaN), and titanium nitride (TiN).

Referring to FIG. 2D, the interconnect hole 410 of the interlayer insulating film 110 on which the diffusion preventing film 150 is formed is filled with the metal 170. For example, the metal 170 may be copper (Cu).

In an exemplary embodiment, after a metal seed layer (not shown) is deposited on the diffusion preventing film 150, the metal may be formed on the metal seed layer using an electroplating method.

Referring to FIG. 2E, the pattern of the metal 170 is formed by removing metals excluding the metal filled in the interconnect hole 410 through the CMP process.

In the case where the metal interconnect 10 in which the pattern of the metal 170 is formed is polished by the CMP process, the diffusion preventing film 150 formed on the upper portion of the interlayer insulating film 110 is removed along with the metals. In addition, a part or the entirety of the hardness controlled unit 130 formed on the upper portion of the interlayer insulating film 110 may be removed along with the metals.

In this process, since the hardness of the hardness controlled unit 130 is high, a frequency of generation of scratches or defects due to the polishing liquid (slurry) on the exposed surface of the interlayer insulating film 110 may be reduced.

Referring to FIG. 2F, the protective film 190 may further be formed on the interlayer insulating film 110 in which the pattern of the metal 170 is formed. The protective film 190 may include silicon nitride (SiNₓ).

According to the manufacturing method of FIGS. 2A to 2E or FIGS. 2A to 2F, the metal interconnect 10 having a single-layer structure is manufactured. Thereafter, by repeating two or more times the manufacturing method of FIGS. 2A to 2E or FIGS. 2A to 2F, a multi-layer metal interconnect may be manufactured.

Since the method of manufacturing the metal interconnect 10 according to the disclosure increases the hardness of the interlayer insulating film 110, surface scratches of the metal interconnect 10 generated during the subsequent CMP process may be reduced. Accordingly, the cause of malfunction such as leakage current or short circuits is removed and thus failure of the metal interconnect 10 is prevented, thereby ensuring reliability.

In addition, the process for increasing the hardness of the interlayer insulating film 110 is a process of performing the nitriding treatment on the surface of the interlayer insulating film 110 by injecting the gas including nitrogen in advance, and thus the process does not require additional apparatuses and raw materials and is simple and economical.

While the present disclosure has been described with respect to the specific embodiments, it will be apparent to those skilled in the art that various changes and modifications may be made without departing from the spirit and scope of the disclosure as defined in the following claims.

What is claimed is:

1. A method of manufacturing a metal interconnect of a semiconductor device comprising
forming a interconnect hole by patterning an interlayer insulating film formed on a substrate;
performing a nitriding treatment on a surface of the interlayer insulating film by injecting a gas including nitrogen into a deposition apparatus in which the substrate is disposed;
forming a diffusion preventing film by injecting the gas including nitrogen and a metal source gas into the deposition apparatus together;
filling the interconnect hole with a metal; and
removing the metal formed on a part other than the interconnect hole by a chemical mechanical polishing (CMP) process.

2. The method of manufacturing a metal interconnect of a semiconductor device according to claim 1,
wherein, in said performing of the nitriding treatment on the surface of the interlayer insulating film by injecting the gas including nitrogen, at least one gas of nitrogen (N₂), ammonia (NH₃), nitrogen monoxide (NO), and nitrogen dioxide (NO₂) is injected.

3. The method of manufacturing a metal interconnect of a semiconductor device according to claim 1,
wherein said performing of the nitriding treatment on the surface of the interlayer insulating film by injecting the gas including nitrogen further comprises applying pulse plasma power to an upper electrode and a lower electrode of the deposition apparatus.

4. The method of manufacturing a metal interconnect of a semiconductor device according to claim 3,
wherein a momentary peak voltage difference of the pulse plasma power is maintained in a range of 1 kV to 10 kV.

5. The method of manufacturing a metal interconnect of a semiconductor device according to claim 1,
wherein said performing of the nitriding treatment on the surface of the interlayer insulating film by injecting the gas including nitrogen further comprises performing a heat treatment on the surface of the substrate.

6. The method of manufacturing a metal interconnect of a semiconductor device according to claim 5,
wherein the surface of the substrate is subjected to the heat treatment at a temperature range of 100° C. to 500° C.

7. The method of manufacturing a metal interconnect of a semiconductor device according to claim 1,
wherein said filling of the interconnect hole with the metal further comprises:
depositing a metal seed layer on the diffusion preventing film; and
forming copper on the metal seed layer using an electroplating method.

8. The method of manufacturing a metal interconnect of a semiconductor device according to claim 1, further comprising:
forming a protective film on the metal interconnect after the CMP process.

9. The method of manufacturing a metal interconnect of a semiconductor device according to claim 1,
wherein said operations are repeated two or more times so as to form a multi-layer metal interconnect.

10. A metal interconnect of a semiconductor device comprising:
an interlayer insulating film in which a interconnect hole is formed;
a hardness controlled unit which is obtained by performing a nitriding treatment on a surface of the interlayer insulating film on an upper portion of the interlayer insulating film and in the vicinity of the interconnect hole;
a diffusion preventing film which is formed on the hardness controlled unit formed in the vicinity of the interconnect hole; and
a metal filled in the interconnect hole.

11. The metal interconnect of a semiconductor device according to claim 10,
wherein the metal includes copper (Cu).

12. The metal interconnect of a semiconductor device according to claim 10,
wherein the interlayer insulating film includes silicon dioxide (SiO₂).

13. The metal interconnect of a semiconductor device according to claim 12,
wherein the interlayer insulating film is made of one of tetraethoxysilicate (TEOS), high-density plasma oxide (HDP-Oxide), and borophosphosilicate glass (BPSG).

14. The metal interconnect of a semiconductor device according to claim 10,
wherein the hardness controlled unit includes silicon nitride (SiNₓ) or silicon oxynitride (SiO_{y}N_{z}).

15. The metal interconnect of a semiconductor device according to claim 10,
wherein a nitrogen concentration of the hardness controlled unit is between about 1% to about 75%.

16. The metal interconnect of a semiconductor device according to claim 10,
wherein a dielectric constant of the hardness controlled unit is lower than that of the interlayer insulating film by about 5% to about 15%.

17. The metal interconnect of a semiconductor device according to claim 10,
wherein the diffusion preventing film includes one of tungsten nitride (WN), tantalum nitride (TaN), and titanium nitride (TiN).

18. The metal interconnect of a semiconductor device according to claim 10,
wherein the metal interconnect has a multi-layer structure.

19. The metal interconnect of a semiconductor device according to claim 10, further comprising a protective film formed on the metal.

20. The metal interconnect of a semiconductor device according to claim 19,
wherein the protective film includes silicon nitride (SiNₓ).
